(19) United States
(12) Patent Application Publication
(10) Pub. No.: US 2023/0088457 A1
(43) Pub. Date: Mar. 23, 2023

(54) ENERGY EFFICIENCY IMPROVEMENT WITH CONTINUOUS FLOW MODULATION IN CLUSTER TOOL

(71) Applicant: Applied Materials, Inc., Santa Clara, CA (US)

(72) Inventors: Lakshmikanth Krishnamurthy SHIRAHATTI, Bangalore (IN); Kirankumar Neelasandra SAVANDAIAH, Bangalore (IN); Thomas BREZOCZKY, Los Gatos, CA (US); Pallab KARMAKAR, Bangalore (IN)

(21) Appl. No.: 17/863,145

(22) Filed: Jul. 12, 2022

Related U.S. Application Data
(60) Provisional application No. 63/245,764, filed on Sep. 17, 2021.

(51) Int. Cl. C23C 14/54; C23C 14/24

(52) U.S. Cl. CPC C23C 14/541; C23C 14/24

(57) ABSTRACT

A substrate processing system that includes a multi-station processing chamber that includes a plurality of process stations is provided. Each process station has one or more processing components cooled by a cooling system. In one embodiment, the cooling system includes a closed loop monitoring system comprising a flow control valve fluidly coupled to a coolant supply line, a valve position measuring system for continuously monitoring the position of the valve, and a valve position controller for adjusting the position of the valve.

### CROSS-REFERENCE TO RELATED APPLICATIONS

This application claims benefit of U.S. provisional patent application Ser. No. 63/245,764, filed Sep. 17, 2021, which is herein incorporated by reference.

### BACKGROUND

### Field

Embodiments described herein generally relate to electronic device manufacturing, and more particularly, to multi-station processing chambers and methods for sequentially forming layers of a multi-layer laminated film stack in a semiconductor device manufacturing process.

### Background

Conventional methods of thin film deposition include depositing thin metal and dielectric films directly on substrates through a sputtering process also known as physical vapor deposition (PVD). In a typical physical vapor deposition process, a target and substrate support having a substrate thereon are disposed in a vacuum chamber. The target is negatively charged, and exposed to an inert gas plasma. Plasma formed gas ions bombard the target and sputter material therefrom such that at least a portion of that material is deposited on the substrate.

Often multiple-chamber processing systems are used to increase processing capability. Typical multiple-chamber processing systems include a transfer chamber and a plurality of processing chambers disposed thereabout. Maintaining uniform process temperature in PVD processes is critical for process requirements, safety and component life. In a typical PVD process, large amounts of heat are generated during processing. Components placed in close proximity to processing region of the chamber can be affected by the heat generated during processing, which can generate extreme temperatures if not adequately controlled. Uncontrolled high temperatures can degrade components over extended periods of time.

Typically in multiple-chamber processing systems cooling temperatures vary from chamber to chamber. Current methods of cooling multiple-chamber processing systems fail to actively monitor and continuously adjust cooling temperatures. Current cooling methods in multiple-chamber processing systems simply flow cooling fluid from the first chamber to the last chamber through interconnected fluid lines without altering the cooling fluids. Thus, as the cooling fluids are used and passed down from chamber to chamber, the cooling fluid temperature increases. This chamber to chamber variation in the cooling fluid results in different process temperatures in each chamber. Chamber to chamber variation in process temperature in turn affects end process results.

Therefore there is a need for a cooling system that is able to solve the problems disclosed above.

### SUMMARY

Embodiments described herein generally relate to electronic device manufacturing, and more particularly, to multi-station processing chambers and methods for sequentially forming layers of a multi-layer laminated film stack in a semiconductor device manufacturing process.

In one embodiment, a substrate processing system comprises a multi-station processing chamber comprising a plurality of process stations. Each process station has one or more processing components cooled by a cooling system comprising a closed loop monitoring system. The closed loop monitoring system comprises an adjustable flow control valve fluidly coupled to a coolant supply line, a valve position measuring system configured to continuously monitor the position of the adjustable flow control valve, and a valve position controller communicatively coupled to the valve position measuring system and the adjustable flow control valve. The valve position controller is configured to adjust the position of the adjustable flow control valve based at least in part on information from the valve position measuring system.

In another embodiment, a substrate processing system comprises a multi-station processing chamber comprising a plurality of process stations. Each process station has a one or more processing components cooled by a cooling system. The cooling system comprises a closed loop monitoring system. The closed loop monitoring system comprises a proportional flow control valve fluidly coupled to a coolant supply line, a valve position controller communicatively coupled to the proportional flow control valve and configured to adjust the proportional flow control valve.

In yet another embodiment, a substrate processing system comprises a multi-station processing chamber comprising a plurality of process stations. Each process station has a plurality of processing components cooled by a cooling system. The cooling system comprises a closed loop monitoring system. The closed loop monitoring system comprises an adjustable flow control valve fluidly coupled to a coolant supply line, a flow meter, fluidly coupled to the coolant supply line, for measuring a flow of coolant through the coolant supply line, and a valve position controller communicatively coupled to the flow meter and the adjustable flow control valve and configured to adjust the adjustable flow control valve based at least in part on measurements from the flow meter.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic plan view of a processing system that includes a multi-station processing chamber with intermittent metrology stations, according to one or more embodiments.

FIG. 2 is a fluid flow schematic of a cooling system according to one or more embodiments.

FIG. 3 is a schematic of the closed loop monitoring system for the cooling system of FIG. 2 according to one embodiment.

FIG. 4 is a schematic of the closed loop monitoring system for the cooling system of FIG. 2 according to one embodiment.

FIG. 5 is a schematic of the closed loop monitoring system for the cooling system of FIG. 2 according to one embodiment.

FIG. 6 is a diagram illustrating a method of using the closed loop monitoring system of FIG. 2 according to one embodiment.

FIG. 7 is a diagram illustrating a method of using the closed loop monitoring system of FIG. 2 according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects of the disclosure provided herein generally provide a substrate processing system that includes at least one transfer chamber that includes a plurality of process stations coupled thereto and a substrate transferring device disposed within a transfer region of the transfer chamber for transferring a plurality of substrates to two or more of the plurality of process stations.

In embodiments described herein, a substrate processing system includes a cooling system for cooling various processing components of the processing system. The cooling system includes a closed loop monitoring system that comprises an adjustable flow control valve fluidly coupled to a coolant supply line, and a valve position controller communicatively coupled to the valve position measuring system and the adjustable flow control valve, and configured to adjust the position of the adjustable flow control valve based at least in part on information from the valve position measuring system.

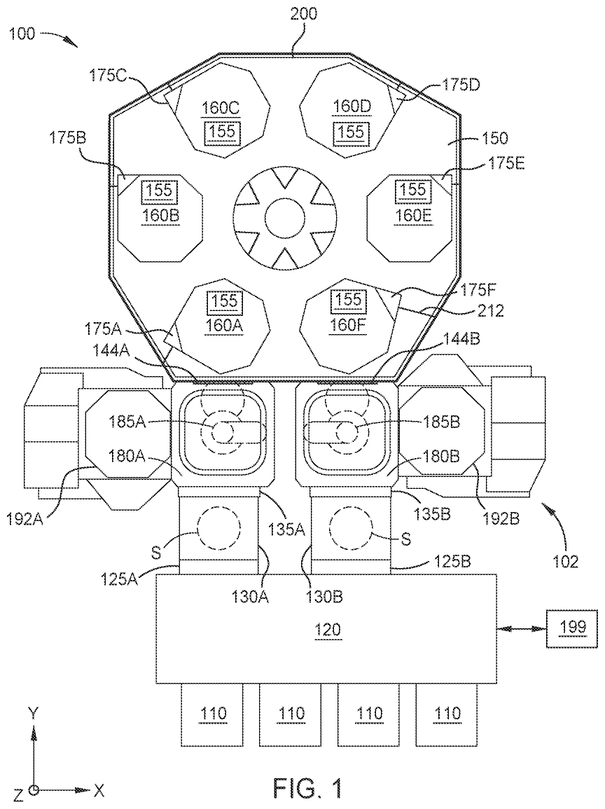

In one embodiment of the disclosure provided herein, a substrate processing system 100 as shown in FIG. 1 includes an atmospheric or ambient pressure substrate input and output handling station also known as a front end 120, a processing module 150 having multiple process stations 160A-160F positioned thereon, and at least one intermediary section 102. While the disclosure provided herein generally illustrates a processing module 150 that includes six process stations 160A-160F, this configuration is not intended to be limiting as to the scope of the invention provided herein, since the processing module 150 might alternatively include: two or more process stations 160; four or more process stations 160; eight or more process stations 160; ten or more process stations 160; or twelve or more process stations 160. A substrate is transferred into the intermediary section 102 from the front end 120 or from the processing module 150, or transferred from the intermediary section 102 to the front end 120 or to the processing module 150.

A substrate loaded into the processing module 150 need not be processed in each of the process stations 160A-160F sequentially. For example, each of the process stations 160A-160F may be a physical vapor deposition (PVD) station that can employ the same sputter target material so that multiple substrates can be processed concurrently in each of the process stations 160A-160F for deposition of a same material layer. Alternatively, different processes may be performed in each adjacent process station of the process stations 160A-160F. In one example, a first deposition process to deposit a first type of film layer is performed in the process stations 160A, 160C and 160E, and a second deposition process to deposit a second type of film layer is performed in the process stations 160A, 160C, and 160E. In yet another alternative example, the substrate is exposed to only two of the process stations 160A-160F. In this example, a first substrate is exposed to only the process stations 160C and 160D, and a third substrate is exposed to only the process stations 160E and 160F. Thus, each substrate can be processed in all of the process stations 160A-160F, and the processes performed at each of the process stations 160A-160F can be the same or different from one or all of the remaining process stations 160A-160F.

Referring again to FIG. 1, the processing system 100 generally includes the processing module 150, the intermediary section 102, which is coupled between the processing module 150 and the front end 120, and a system controller 199. As shown in FIG. 1, the intermediary section 102 includes a pair of loadlock chambers 130A, 130B and a pair of intermediary robot chambers 180A, 180B. Each individual load lock chamber is separately connected through a respective first valve 125A, 125B, at one side thereof to the front end 120, and through a respective second valve 135A, 135B, to one of the intermediary robot chambers 180A, 180B, respectively. During operation a front end robot (not shown) in the front end 120 moves a substrate therefrom into a loadlock chamber 130A or 130B, or removes a substrate from a loadlock chamber 130A, 1306. Then an intermediary robot 185A, 1856 in one of the associated intermediary robot chambers 180A, 180B connected to an associated one of the loadlock chambers 130A, 130B moves a substrate from the loadlock chamber 130A or loadlock chamber 130B and into the corresponding intermediary robot chamber 180A, 180B. In one embodiment, the intermediary section 102 also includes a preclean/degas chamber 192 connected to an intermediate robot chamber 180. For example, a pre-clean/degas chamber 192A may be connected to an intermediary robot chamber 180A and a pre-clean/degas chamber 192B may be connected to intermediary robot chamber 180B.

A substrate loaded into one of the loadlock chambers 130A, 1306 from the front end 120 is moved, by the associated intermediary robot 185A or 185B, from the loadlock chamber 130A or 1306 and into the pre-clean/degas chamber 192A or 1926. In the pre-clean/degas chambers 192A, 1926, the substrate is heated to volatilize any adsorbed moisture or other volatilizable materials therefrom, and is subjected to a plasma etch process whereby residual contaminant materials thereon are removed. Thereafter, the substrate is moved by the appropriate associated intermediary robot 185A or 185B back into the corresponding intermediary robot chamber 180A or 180B and thence onto a substrate support at a process station 160 in the processing module 150, here process station 160A or 160F. In some embodiments, once the substrate (S) is placed on the substrate support, it remains thereon until all processing thereof in the processing module 150 is completed.

Here, each loadlock chamber 130A,130B is connected to a vacuum pump (not shown), for example a roughing pump, the output of which is connected to an exhaust duct (not shown), to reduce the pressure within the loadlock chamber 130A, 130B to a sub-atmospheric pressure on the order of about 10⁻³ torr. Each loadlock chamber 130A or 130B may be connected to a vacuum pump dedicated thereto, or a vacuum pump shared with one or more components within the processing system 100, or to a house exhaust other than a vacuum pump to reduce the pressure therein. In each case, a valve (not shown) can be provided on each loadlock chamber 130A, 130B exhaust to the pump or house exhaust to isolate, or substantially isolate, the pumping outlet of each loadlock chamber 130A, 130B connected to the vacuum pump or house exhaust from the interior volume of each loadlock chamber 130A, 130B when the first valve 125A or 125B respectively is open and the interior of each loadlock chamber 130A, 130B is exposed to atmospheric or ambient pressure conditions.

After the substrate has been processed, for example, in the, pre-clean/degas chamber 192B, the intermediary robot 185B removes the substrate from the pre-clean/degas chamber 192B. A process chamber valve 144B, which is disposed between the intermediary robot chamber 180B and the processing module 150, is opened to expose an opening formed in a wall of the processing module 150, and the intermediary robot 185B moves the substrate through the opening to the process station 160F of the processing module 150 where it is received for processing within one or more of the process stations 160A-160F of the processing module 150. In the same manner, a substrate can be moved from the front end 120 through the loadlock chamber 130A, to the pre-clean/degas chamber 192A, and then to the processing module 150 through a process chamber valve 144A and an opening in the processing module 150 wall to be received at the process station 160A. Alternatively, the process chamber valves 144A, 144B may be eliminated, and intermediary robot chambers 180A, 180B be in direct uninterrupted fluid communication with the interior of the processing module 150.

Each of the loadlock chambers 130A, 130B and intermediary robot chambers 180A, 180B are configured to pass substrates from the front end 120 into the processing module 150, as well as from the processing module 150 and into the front end 120. Thus, with respect to the first intermediary robot chamber 180A, to remove a substrate positioned at the process station 160A of the processing module 150, the process chamber valve 144A is opened, and the intermediary robot 185A removes the substrate from the process station 160A and moves it, through an open second valve 135A connected between the intermediary robot chamber 180A and the loadlock chamber 130A, to place the substrate in the loadlock chamber 130A. The end effector of the intermediary robot 185A on which the substrate was moved is retracted from the loadlock chamber 130A, the second valve 135A thereof is closed, and the interior volume of the loadlock chamber 130A is optionally isolated from the vacuum pump connected thereto. Then the first valve 125A connected to the loadlock chamber 130A is opened, and the front end 120 robot picks up the substrate in the loadlock chamber 130A and moves it to a storage location, such as a cassette or FOUP 110, located within or connected to a sidewall of, the front end 120. In a similar fashion, using the intermediary robot chamber 180B, the intermediary robot 185B, the loadlock chamber 130B and associated valves 135B and 125B thereof, a substrate can be moved from the process station 160F location to the front end 120. During the movement of a substrate from the processing module 150 to the front end 120, a different substrate may be located within each pre-clean/degas chamber 192A, 192B connected to the intermediary robot chamber 180A, 180B through which the substrate being moved to the front end 120 passes. Because each pre-clean/degas chamber 192A, 192B is isolated from the intermediary robot chamber 180A, 180B to which it is attached by a valve, passage of a different substrate can be undertaken from the processing module 150 to the front end 120 without interfering with the processing of a substrate in each respective pre-clean/degas chambers 192A, 192B.

The system controller 199 controls activities and operating parameters of the automated components found in the processing system 100. In general, the bulk of the movement of a substrate through the processing system is performed using the various automated devices disclosed herein by use of commands sent by the system controller 199. The system controller 199 is a general use computer that is used to control one or more components found in the processing system 100. The system controller 199 is generally designed to facilitate the control and automation of one or more of the processing sequences disclosed herein and typically includes a central processing unit (CPU) (not shown), memory (not shown), and support circuits (or I/O) (not shown). Software instructions and data can be coded and stored within the memory (e.g., non-transitory computer readable medium) for instructing the CPU. A program (or computer instructions) readable by the processing unit within the system controller determines which tasks are performable in the processing system. For example, the non-transitory computer readable medium includes a program which when executed by the processing unit is configured to perform one or more of the methods described herein. Preferably, the program includes code to perform tasks relating to monitoring, executing and controlling the movement, support, and/or position of a substrate along with the various process recipe tasks being performed.

The processing system 100 further includes a cooling system 200. The cooling system is used to cool various processing chamber components. Maintaining uniform temperature of the chamber components is critical to meeting process requirements, by reducing time required to resume operation of the substrate processing system. The cooling system 200 includes a thermocouple (not shown) and a variable flow control valve (not shown). The thermocouple is a mounting that sits in a coolant supply line 212 in between a manifold 175 and each of the process stations 160A-160F.

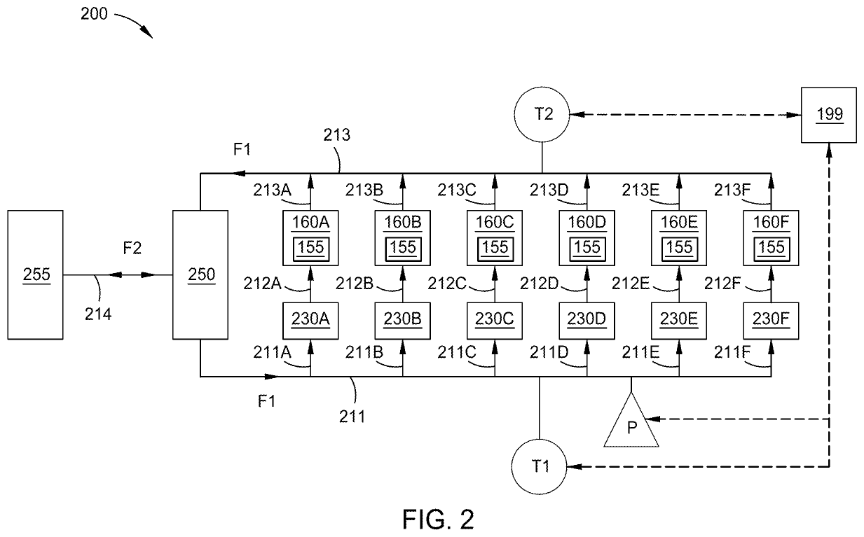

FIG. 2 is a fluid flow schematic of the cooling system 200. As seen in FIG. 2, the cooling system 200 includes a plurality of coolant lines 211, 212, 213, 214, a first fluid F1, a second fluid F2, a plurality of closed loop monitoring systems 230, a plurality of process stations 160 (which may be the process stations 160A-160F of processing module 150 in FIG. 1), a first heat exchanger 250, a second heat exchanger 255, a first temperature sensor T₁, a second temperature sensor T₂ and a pressure sensor P.

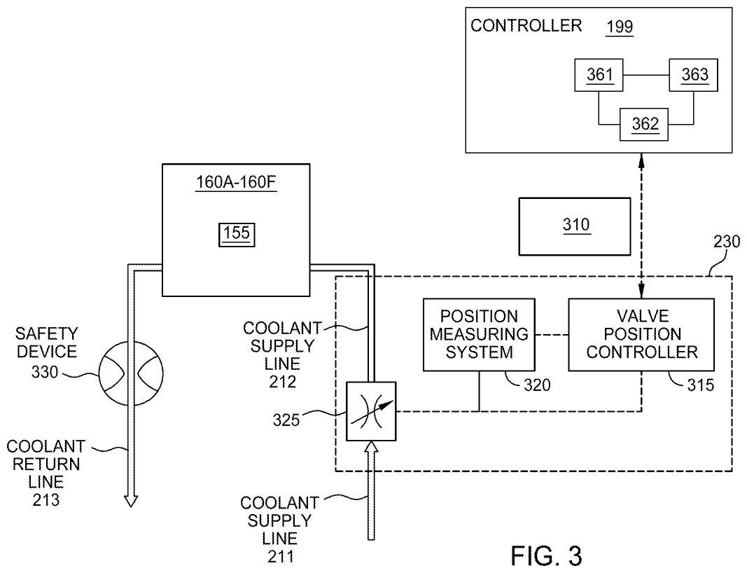

Each coolant line 211A-211F, 212A-212F, 213A-213F is associated with a respective process station 160A-160F and is coupled to various process components within each process station 160A-160F. Examples of process components include: a process adapter, a process source (i.e., target) and a pedestal. Coolant supply lines 211 and 212 (i.e., coolant supply lines) supply cooling fluids from the first heat exchanger 250 to the various process components of the process stations 160A-160F. Coolant return lines 213 return cooling fluids from the process components of the process stations to the first heat exchanger 250. Cooling fluid F1 is supplied to the first heat exchanger 250 where it is cooled prior to entering the coolant supply lines 211. The first heat exchanger 250 includes a cooling pump (not shown) to circulate cooling fluid F1 through the cooling system 200. The cooling fluid F1 is pumped from the first heat exchanger 250 to the plurality of closed loop monitoring systems 230 through the coolant supply lines 211. The closed loop monitoring systems 230 help reduce the thermal gradient throughout the processing system. Reducing the thermal gradient saves energy and reduces mean times between process cycles. As seen further in FIGS. 3-5, each closed loop monitoring system 230 is positioned between a variable flow control valve and a thermocouple. As seen in FIG. 2, cooling fluid F1 flows through the closed loop monitoring system 230 and into each process station 160A-160F through coolant supply lines 212A-212F along the direction of the arrows.

After flowing through the process stations 160A-160F of the processing system 100 the cooling fluid F1 is returned to the first heat exchanger 250 through the coolant return lines 213, where it is cooled again before being returned to the coolant supply lines 211.

As previously mentioned, the cooling system includes a plurality of temperature sensors, and a pressure sensor. A first temperature sensor T1 is coupled to the coolant supply line 211. The first temperature sensor T₁ is positioned before the plurality process stations 160A-160F, between the first heat exchanger 250 and the plurality of closed loop monitoring systems 230. The first temperature sensor T1 is used to monitor the temperature of the coolant F1 (i.e., cooling fluid) prior to entering the closed loop monitoring systems 230A-230F and process stations 160A-160F. Data gathered by the first temperature sensor T1 is relayed to a system controller 199. This data is used to determine a first temperature of the coolant prior to cooling the various process components of process stations 160A-160F. A second temperature sensor T2 is coupled to the coolant return line 213. The second temperature sensor T2 is positioned after the plurality to process stations 160A-160F, between the plurality of process stations 160A-160F and the first heat exchanger 250. The second temperature sensor T2 is used to monitor the temperature of the coolant F1 after flowing through and cooling the various process components of process stations 160A-160F. Data gathered by the second temperature sensor T2 is relayed to the system controller 199. This data is used to determine a second temperature of the coolant after cooling the various process components of the process stations 160A-160F. The system controller 199 uses input from the first temperature sensor T1 and second temperature sensor T2 to adjust the flow rate through each process station 160A-160F based on rise in measured temperature.

In addition to the first and second temperature sensors T1, T2, the cooling system 200 includes a pressure sensor P, coupled to the coolant supply line 211. The pressure sensor P is positioned before the plurality of process stations 160A-160F, between the first heat exchanger 250 and the plurality of closed loop monitoring systems 230. The pressure sensor P is used to monitor the pressure of the coolant F1 prior to entering the closed loop monitoring systems 230A-230F and process stations 160A-160F. Data gathered by the pressure sensor is relayed to the system controller 199.

The cooling system 200 further includes a second heat exchanger 255. In one configuration, the second heat exchanger 255 is an evaporative condenser (e.g., a swamp cooler). The second heat exchanger 255 circulates cooling fluid F2 through a plurality of coils positioned on, within or around the first heat exchanger 250 to help cool the cooling fluid passing through the first heat exchanger 250. The second heat exchanger 255 uses cooling fluid provided by coolant supply line 211. As seen in FIG. 2, cooling fluid F2 is cooled by the second heat exchanger 255 before flowing through the first heat exchanger 250, and then is returned to the second heat exchanger to be cooled again.

FIG. 3 depicts a schematic of the closed loop monitoring system 230 of the cooling system 200 according to one embodiment. The closed loop monitoring system 230 includes a valve position measuring system 320, a flow control valve 325 and a valve position controller 315. In addition to the closed loop monitoring system 230, FIG. 3 shows the coolant supply line 211, the coolant supply line 212, an electrical coupling 310 (e.g., ethernet cable (ECAT)), a system controller 199 (which may be included in the system controller 199), one of the process station 160A-160F, a safety device 330 (i.e., a flow switch), and the coolant return line 213.

The flow rate of the cooling fluid F1 is adjusted by the system controller 199. Here, the system controller 199 includes a programmable central processing unit (CPU) 361 which is operable with a memory 362 (e.g., non-volatile memory) and support circuits 363. The support circuits 363 are conventionally coupled to the CPU 161 and comprise cache, clock circuits, input/output subsystems, power supplied and the like coupled to the various components of the closed loop monitoring system 230 to facilitate control thereof. The CPU 361 is one of any form of general purpose computer processors used in an industry setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), in which when executed by the CPU 161, facilitates the closed loop monitoring system 230. The instructions can conform to any one of a number of different programming languages, so long as they enable the functions of the embodiments and methods disclosed herein. For example, the disclosure may be implemented as a program (in any language) stored on computer-readable storage media for processing a substrate as disclosed herein.

Illustrative non-transitory computer-readable storage media include, but are not limited to: (1) non-writable storage media (e.g., read-only memory devices within a computer such as CD-ROM disk readable by a CS-ROM drive, flash memory, ROM chips or any type of solid-state non-volatile semiconductor memory devices, e.g., solid state drives (SSD) on which information may be permanently stored; and (2) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations.

In some configurations, the system controller 199 is a proportional integral derivative (PID) controller. PID controllers use a control loop feedback mechanism to control process variables such as temperature, flow, pressure, etc. Here, the system controller 199 uses temperature input from the temperature sensor T1, and the temperature sensor T2, to adjust the flow rate of coolant through the coolant supply line 211 to each process station 160A-160F based on the measured temperature at the temperature sensor T2 coupled to the coolant return line 213.

As seen in FIG. 3, the system controller 199 is electrically coupled to the closed loop monitoring system 230 through an electrical coupling 310, but may be connected in alternative conventional ways. In some configurations, the system controller 199 is electrically coupled to the valve position controller 315. The valve position controller 315 communicates with both the valve position measuring system 320, and the flow control valve 325. The flow control valve 325 is coupled to the coolant supply line 211, and alters the flow of coolant through the coolant supply line 211 and into the coolant supply line 212 prior to entering the process station 160A-160F. In one embodiment, the flow control valve 325 is a motor driven, bi-directional 2-way valve for continuous flow control.

The flow control valve 325 can operate in three different modes: a step flow control mode which includes four steps, a slow on/off mode, and a continuous flow control mode. In an open position, the flow control valve 325 allows coolant to freely flow through the coolant supply line 211. In a closed position, the flow control valve 325 prevents coolant from flowing through the coolant supply line 211. However, the flow control valve 325 is not limited to being completely opened or completely closed. Typically, the flow control valve 325 will be either partially open or partially closed depending on the communication by the valve position controller 315 based on the valve position measuring system 320. A partially open or partially closed valve incrementally adjusts the flow rate of the coolant flowing through the coolant supply line 211. Typical valve operation is expected between 30 percent and 55 percent. At 30 percent, the flowrate of coolant is about 0.5 GPM. At 45 percent, the flowrate of coolant is about 1 GPM and at 55 percent, the flowrate of coolant is about 1.2 GPM.

The closed loop monitoring system 230 monitors the position of the flow control valve 325. Based on the measurement in either temperature sensor T1 or temperature sensor T2 or both, the system controller 199 communicates with the valve position controller 315 to adjust the position of the flow control valve 325. The communication between the system controller 350, the valve position measuring system 320, and the valve position controller 315 forms a closed loop. The closed loop allows the valve position measuring system 320 and the valve position controller 315 to continuously communicate to actively adjust the position of the flow control valve 325.

The safety device 330 in FIG. 3 includes an electric switch, which is either on or off depending on the flow of the coolant through the coolant return line 213. If there is insufficient flow of coolant through the coolant return line 213, the coolant will not adequately cool the source, or in some cases boil. The electric switch is coupled to various processing components 155. The electric switch will open if there is no coolant flow through coolant return line 213, and will close if there is sufficient coolant flow through the coolant return line 213. During normal operation, there will be sufficient coolant flow, and the switch will be in the closed position. If the electric switch is in the open position, the processing system will stop to prevent damage to the various processing system components.

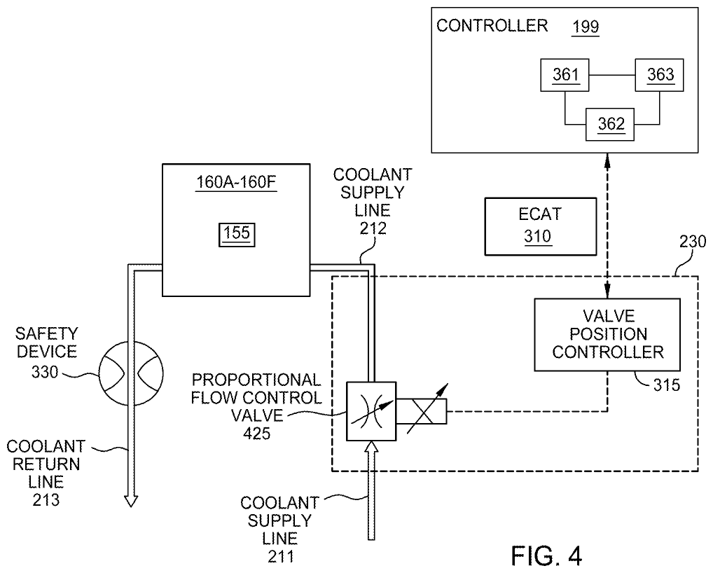

FIG. 4 depicts a schematic of an alternative configuration of the closed loop monitoring system 230 of the cooling system 200 according to one embodiment. Here, the closed loop monitoring system 230 includes a proportional flow control valve 425, the valve position controller 315, the electrical coupling 310, and the system controller 199. In addition to the closed loop monitoring system 230, FIG. 4 includes the coolant supply lines 211 and 212, one of the process stations 160A-160F, the safety device 330, and the coolant return line 213.

Here, the proportional flow control valve 425 is a two way direct-acting solenoid proportional control valve. The proportional flow control valve 425 is a valve used to control fluid flow rate by varying the size of the flow passage via a restrictor. Typically the restrictor valve is directed by a signal from a controller. The proportional flow control valve 425 uses a solenoid as an actuator for variable valve positioning in the closed control loop. A direct-operated 2-way standard proportional solenoid valve as used herein operates very similarly to a direct-operated solenoid valve with the exception that the direct-operated 2-way standard proportional solenoid valve operates through a range of valve positioning while the direct-operated solenoid valve only provides two switching states (on/off).

Here, the valve position controller 315 is communicatively coupled to the proportional flow control valve 425 and the system controller 199 via the electrical coupling 310. The system controller 199 uses temperature data from the temperature sensor T1 and temperature sensor T2 to adjust the flow rate of coolant to the various processing components 155. By relaying instructions to the valve position controller 315, the system controller 199 is able to adjust the proportional flow control valve 425 and alter the flow rate of coolant through the coolant supply line 211 into the various processing components 155.

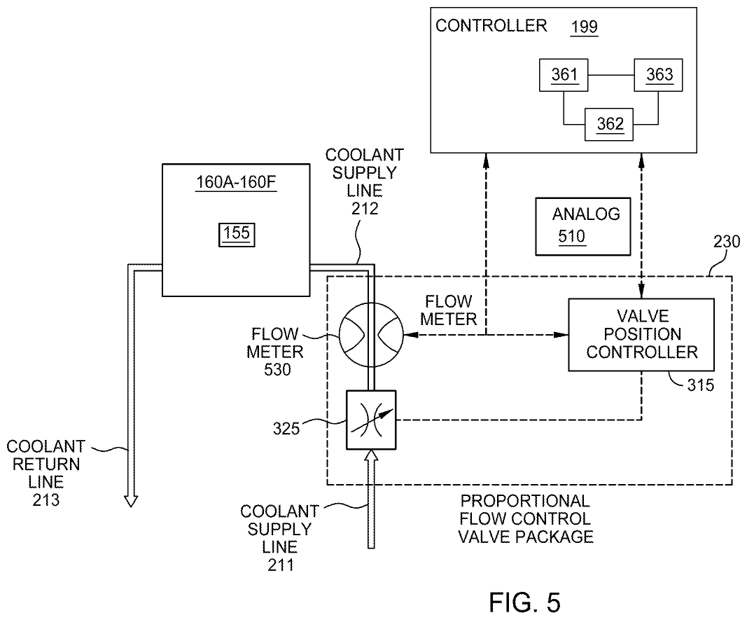

FIG. 5 depicts a schematic of an alternative configuration of the closed loop monitoring system 230 of the cooling system 200, according to one embodiment. Here, the closed loop monitoring system 230 includes a flow meter 530, the flow control valve 325, the valve position controller 315, an analog transmission line 510, and the system controller 199. In addition to the closed loop monitoring system 230, FIG. 5 includes the coolant supply lines 211 and 212, one of the process stations 160A-160F and the coolant return line 213.

The flow meter 530 is coupled to the coolant supply line 211, and is positioned between the flow control valve 325 and the process station 160A-160F. The flow meter 530 measures the linear volumetric flow rate of coolant through the coolant supply lines 211 and 212 into the process station 160A-160F. In this configuration, the flow meter 530 communicates with both the system controller 199 and the valve position controller 315 through the analog transmission line 510. The flow meter 530 can also independently communicate with either the system controller 199 or the valve position controller 315. In configurations where the flow meter 530 does not communicate directly with the system controller 199, information regarding the linear volumetric flow rate of coolant is relayed to the system controller 199 through the valve position controller 315. In either configuration, the system controller 199 uses information gathered by the flow meter 530 to adjust the flow of coolant into the process station 160A-160F through coolant supply line 212 by adjusting the position of the flow control valve 325 using the valve position controller 315.

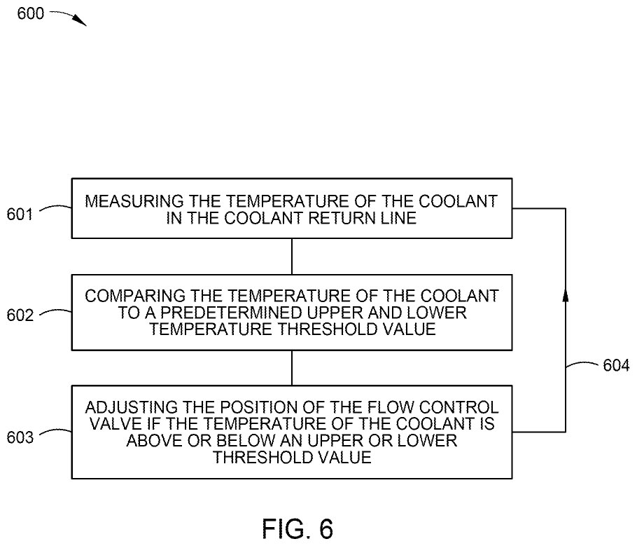

FIG. 6 is a diagram illustrating a method of using the closed loop monitoring system 230 according to one embodiment. The method includes measuring the temperature of the coolant in the coolant return line 213, comparing the temperature of the coolant to a predetermined upper and lower threshold value, and adjusting the position of the flow control valve 325 if the temperature is above or below an upper or low threshold value. At the outset, the cooling fluid F1 is assumed to be flowing through the cooling system at full flow, while the temperature of the outlet fluid is measured by the temperature sensor T2.

At activity 601, the method 600 includes measuring the temperature of the coolant in the coolant return line 213. The temperature of the coolant in the coolant return line 213 is measured by the temperature sensor T2 coupled to the coolant return line 213. The temperature measurement is relayed to the system controller 199 as temperature data. This temperature data is stored at the system controller 199.

At activity 602, the method 600 includes comparing the measured temperature data of the coolant in the coolant return line 213 to a predetermined upper and lower temperature threshold value stored in the system controller 199. Here, the system controller compares the temperature of the coolant in the coolant return line 213 to a predetermined upper and lower threshold value store on the system controller 199. The system controller 199 then determines whether the flow rate of coolant must be adjusted, so that the temperature of coolant is within the threshold values.

At activity 603, the method 600 includes adjusting the position of the flow control valve 325 if the temperature measurement of the coolant in the coolant return line 213 is above the upper threshold value or below the lower threshold value. The controller uses input from temperature sensor T2 to adjust the flow rate through each process station 160A-160F based on the measured temperature. If the temperature is above the threshold value, the flow of coolant is increased. If the temperature is below the threshold value, the flow of coolant is decreased. As previously mentioned the coolant flow is continuously adjusted by using the valve position controller 315 to alter the position of both the flow control valve 325 and the proportional flow control valve 425.

At activity 604, the method 600 includes repeating activities 601-603 throughout the processing activities in the processing system 100.

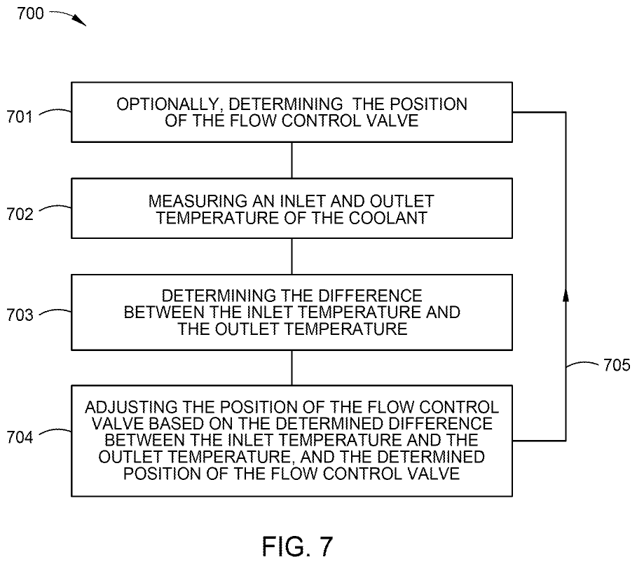

FIG. 7 is a diagram illustrating a method of using the closed loop monitoring system 230 according to one embodiment. The method includes optionally determining the position of the flow control valve 325, measuring a first inlet and second inlet temperature of the coolant, determining the difference between the first inlet temperature and the first outlet temperature, and adjusting the position of the flow control valve 325 based on the determined difference between the first inlet temperature and the first outlet temperature and the determined position of the flow control valve 325.

At activity 701, the method 700 includes optionally determining the position of the flow control valve. In some configurations, the position of the flow control valve 325 is determined by the position measuring system 320, and communicated to the system controller 199 through the valve position controller 315. By maintaining constant communication with the valve position controller 315, the system controller 199 is able to adjust the position of the flow control valve 325 based on the determined position by the position measuring system 320.

At activity 702, the method 700 includes measuring a first inlet and first outlet temperature of the coolant wherein the inlet temperature is the temperature of the coolant in the coolant supply line 211, and the outlet temperature is the temperature of the coolant in the coolant return line 213. The temperature of the inlet coolant is measured by the temperature sensor T1 and the temperature of the outlet coolant is measured by the temperature sensor T2. The temperature measurement is relayed to the system controller 199 as temperature data. This temperature data is stored at the system controller 199.

At activity 703, the method 700 includes determining the difference between the first inlet temperature and the first outlet temperature. The rise in temperature between the first inlet temperature and the first outlet temperature is determined by the system controller 199.

At activity 704, the method 700 includes adjusting the position of the flow control valve 325 based on the determined difference between the first inlet temperature and the first outlet temperature, and, if applicable, the determined position of the flow control valve. The rise in temperature is compared to a setpoint value at the system controller 199. If the rise in temperature of the coolant is above the setpoint value, then the flow of coolant is increased. If the rise in temperature of the coolant is below the setpoint value, then the flow of coolant is decreased. As previously mentioned, coolant flow is continuously adjusted by using the valve position controller 315 to alter the positon of both the flow control valve 325 and the proportional flow control valve 425.

At activity 705, the method 700 includes repeating activities 701-704 throughout the processing activities in the processing system 100.

Thus, the closed loop monitoring system 230 improves the efficiency of the processing system by reducing the energy requirement and the mean times between process cycles. In one embodiment, the closed loop monitoring system 230 includes the adjustable flow control valve 325, the valve position controller 315 and the valve position measuring system 320 communicatively coupled to the system controller 199. In an alternative embodiment, the closed loop monitoring system 230 includes the proportional flow control valve 425, fluidly coupled to the coolant supply line 211, and the valve position controller 315 communicatively coupled to the proportional flow control valve 425 and configured to adjust the proportional flow control valve 425. In yet another embodiment, the closed loop monitoring system 230 includes the adjustable flow control valve 325 fluidly coupled to the coolant supply line 211, the flow meter 530 fluidly coupled to the coolant supply line 211 for measuring the flow of coolant through the coolant supply line 211, and the valve position controller 315 communicatively coupled to the flow meter 530 and the adjustable flow control valve 325 and configured to adjust the adjustable flow control valve based at least in part on measurements from the flow meter 530.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a multi-station processing chamber comprising a plurality of process stations, each process station having one or more processing components cooled by a cooling system comprising:
a closed loop monitoring system comprising:
an adjustable flow control valve fluidly coupled to a coolant supply line;
a valve position measuring system configured to continuously monitor the position of the adjustable flow control valve; and
a valve position controller communicatively coupled to the valve position measuring system and the adjustable flow control valve, and configured to adjust the position of the adjustable flow control valve based at least in part on information from the valve position measuring system.

2. The system of claim 1, further including a flow switch fluidly coupled to a coolant return line fluidly coupled to the one or more processing components.

3. The system of claim 2, further including a first temperature sensor coupled to the coolant supply line.

4. The system of claim 3, further including a second temperature sensor coupled to the coolant return line.

5. The system of claim 4, further including a pressure sensor coupled to the coolant supply line.

6. The system of claim 5, further including a first heat exchanger fluidly coupled to the coolant supply line and the coolant return line.

7. The system of claim 1, further comprising a system controller communicatively coupled to the valve position controller.

8. The system of claim 7, wherein the system controller includes instruction that, when executed, cause a plurality of operations to be conducted, the plurality of operations comprising:
determining the position of the flow control valve;
measuring a first inlet temperature of coolant in the coolant supply line;
measuring a first outlet temperature of coolant in a coolant return line fluidly coupled to the one or more processing components;
determining a difference between the first inlet temperature and the first outlet temperature; and
adjusting the position of the flow control valve based on the determined difference between the first inlet temperature and the first outlet temperature, and the determined position of the flow control valve.

9. The system of claim 8, wherein the plurality of operations further comprise:
measuring a second inlet temperature of coolant in the coolant supply line;
measuring a second outlet temperature of coolant in the coolant return line;
determining the difference between the second inlet temperature and the second outlet temperature; and
adjusting the position of the flow control valve based on the determined difference between the second inlet temperature and the second outlet temperature, and the determined position of the flow control valve.

10. A substrate processing system, comprising:
a multi-station processing chamber comprising a plurality of process stations, each process station having a one or more processing components cooled by a cooling system comprising:
a closed loop monitoring system comprising:
a proportional flow control valve fluidly coupled to a coolant supply line; and
a valve position controller communicatively coupled to the proportional flow control valve and configured to adjust the proportional flow control valve.

11. The system of claim 10, wherein the proportional flow control valve is a 2 way direct-acting solenoid proportional control valve.

12. The system of claim 10, further including a first temperature sensor coupled to the coolant supply line, and a pressure sensor coupled to the coolant supply line.

13. The system of claim 12, further including a second temperature sensor coupled to a coolant return line fluidly coupled to the one or more processing components.

14. The system of claim 13, further including a first heat exchanger fluidly coupled to the coolant supply line and the coolant return line.

15. The system of claim 10, further comprising a system controller including instruction that, when executed, causes a plurality of operations to be conducted, the plurality of operations comprising:
measuring a first inlet temperature of coolant in the coolant supply line;
measuring a first outlet temperature of coolant in a coolant return line coupled to the one or more processing components;
determining a difference between the first inlet temperature and the first outlet temperature; and
adjusting the position of the flow control valve based on the determined difference between the first inlet temperature and the first outlet temperature.

16. The system of claim 15, wherein the plurality of operations further comprise:
measuring a second inlet temperature of coolant in the coolant supply line;
measuring a second outlet temperature of coolant in the coolant return line;
determining the difference between the second inlet temperature and the second outlet temperature; and
adjusting the position of the flow control valve based on the determined difference between the second inlet temperature and the second outlet temperature.

17. A substrate processing system, comprising:
a multi-station processing chamber comprising a plurality of process stations, each process station having a plurality of processing components cooled by a cooling system comprising:
a closed loop monitoring system comprising:
an adjustable flow control valve fluidly coupled to a coolant supply line;
a flow meter, fluidly coupled to the coolant supply line, for measuring a flow of coolant through the coolant supply line; and
a valve position controller communicatively coupled to the flow meter and the adjustable flow control valve and configured to adjust the adjustable flow control valve based at least in part on measurements from the flow meter.

18. The system of claim 17, further comprising a system controller communicatively coupled to the flow meter.

19. The system of claim 17, wherein the flow control valve is a stepper motor with a PID controller.

20. The system of claim 17, further comprising a system controller including instruction that, when executed, cause a plurality of operations to be conducted, the plurality of operations comprising:
measuring a first inlet temperature of coolant in the coolant supply line;
measuring a first outlet temperature of coolant in a coolant return line coupled to the one or more processing components;
determining a difference between the first inlet temperature and the first outlet temperature; and
adjusting the position of the flow control valve based on the determined difference between the first inlet temperature and the first outlet temperature and measurements from the flow meter.

21. The system of claim 20, wherein the plurality of operations further comprise:
measuring a second inlet temperature of coolant in the coolant supply line;
measuring a second outlet temperature of coolant in the coolant return line;
determining the difference between the second inlet temperature and the second outlet temperature; and
adjusting the position of the flow control valve based on the determined difference between the second inlet temperature and the second outlet temperature and measurements from the flow meter.
